(19) United States
(12) Patent Application Publication
(10) Pub. No.: US 2011/0088766 A1
(43) Pub. Date: Apr. 21, 2011

(54) Thin-Film Photovoltaic Device and Method for Manufacturing the Same

(75) Inventors: Min-Chuan Wang, Chiayi City (TW); Yong-Zhi Chen, Chiayi County (TW); Der-Jun Jan, Taoyuan County (TW); Chi-Fong Ai, Taoyuan County (TW)

(73) Assignee: Institute of Nuclear Energy Research Atomic Energy Council, Executive Yuan, Taoyuan County (TW)

(21) Appl. No.: 12/726,930

(22) Filed: Mar. 18, 2010

(30) Foreign Application Priority Data
Oct. 20, 2009 (TW) 098135360

(51) Int. Cl. H01L 31/0224; H01L 31/18

(52) U.S. Cl. 136/256; 438/98; 257/E31.126

(57) ABSTRACT

A thin-film photovoltaic device comprising at least: a substrate, a transparent electrode layer, a p-type semiconductor as the ohmic contact layer, an intrinsic semiconductor as the light absorption layer, and a magnesium alloy substituted for the n-type semiconductor as the other ohmic contact layer. A method for manufacturing the thin-film photovoltaic device is also provided in the present invention.

### BACKGROUND OF THE INVENTION

1. Field of the Invention

The present invention generally relates to a thin-film photovoltaic device and a method for manufacturing the same and, more particularly, to a silicon thin-film photovoltaic device comprising a magnesium alloy layer and a method for manufacturing the silicon thin-film photovoltaic device.

2. Background of the Invention

In recent years, global warming due to the green house effect has become the most important problem and, therefore, the development in clean energy is a trend that is inevitable to come. Among the renewable energies, the solar energy has attracted the most attention because the photovoltaic device based on the photovoltaic effect generates power without producing carbon dioxide, which is of significant contribution to slow down the aggravation of global warming. However, crystalline silicon is intensely demanded by the semiconductor, liquid crystal display (LCD) and photovoltaic industries, which causes a shortage in crystalline silicon materials to adversely affect the development in crystalline silicon photovoltaic devices. Accordingly, the amorphous silicon thin-film photovoltaic device has become a candidate for mass production in the photovoltaic industry.

FIG. 1A is a cross-sectional view of a conventional thin-film photovoltaic device using a glass substrate. In FIG. 1A, the thin-film photovoltaic device 1 comprises, from the bottom up, a glass substrate 11, a transparent electrode layer 12, a p-type semiconductor layer 13, an intrinsic semiconductor layer 14, an n-type semiconductor layer 15 and a metal electrode layer 16.

FIG. 1B is a cross-sectional view of a conventional thin-film photovoltaic device using a stainless steel substrate. In FIG. 1B, the thin-film photovoltaic device 10 comprises, from the bottom up, a stainless steel substrate 101, an insulating layer 102, a metal electrode layer 103, an n-type semiconductor layer 104, an intrinsic semiconductor layer 105, a p-type semiconductor layer 106 and a transparent electrode layer 107.

In FIG. 1A and FIG. 1B, the contact between the n-type semiconductor layer and the metal electrode layer is a Schottky contact to result in high resistance and thus low performance. Therefore, it has become an important topic for the thin-film photovoltaic device to reduce the contact resistance by forming an Ohmic contact instead of a Schottky contact.

On the other hand, in the manufacture of large-area thin-film photovoltaic devices, plasma-enhanced chemical vapor-phase deposition (PECVD) is used for the formation of the thin film. The basic structure of the thin-film photovoltaic device is as shown in FIG. 1A and FIG. 1B to comprise a p-type semiconductor layer, an intrinsic semiconductor layer, and an n-type semiconductor layer. Generally, the basic structure of the thin-film photovoltaic device can be formed by PECVD. However, the device characterization may be degraded due to cross-contamination of gaseous dopants when the three layers are formed in the same chamber. More particularly, in the PECVD process, a p-type semiconductor layer is formed using gas source B₂H₆. Then, prior to the deposition of the intrinsic semiconductor layer, the residual B₂H₆ has to be removed from the chamber; otherwise, the intrinsic semiconductor layer will be contaminated to cause structural defects and thus enhance electron-hole pair recombination.

Therefore, there is need in providing a thin-film photovoltaic device and a method for manufacturing the same to overcome the aforesaid problems without increasing the manufacturing cost.

### SUMMARY OF THE INVENTION

It is one object of the present invention to provide a thin-film photovoltaic device comprising a magnesium alloy layer to enhance the Ohmic contact between the semiconductor layer and the metal electrode layer to improve the opto-electronic performances.

It is another object of the present invention to provide a method for manufacturing a thin-film photovoltaic device to avoid cross-contamination of gaseous dopants during the PECVD process.

The thin-film photovoltaic device and the method for manufacturing the same according to the present invention have advantages herein:

1. Enhanced Ohmic contact between the semiconductor layer and the metal electrode layer to improve the opto-electronic performances of the thin-film photovoltaic devic;

2. A magnesium alloy layer as a back reflector to reflect the electro-magnetic radiation unabsorbed by the light absorption layer (the intrinsic semiconductor layer) to pass the light absorption layer again to increase absorbility;

3. Free of cross-contamination of gaseous dopants during the PECVD process so as to prevent the performances of the device from being degraded; and

4. Lowered manufacturing cost because no gaseous dopants are required.

### BRIEF DESCRIPTION OF THE DRAWINGS

The objects and spirits of several embodiments of the present invention will be readily understood by the accompanying drawings and detailed descriptions, wherein:

FIG. 1A is a cross-sectional view of a conventional thin-film photovoltaic device using a glass substrate;

FIG. 1B is a cross-sectional view of a conventional thin-film photovoltaic device using a stainless steel substrate;

FIG. 1C shows that an excellent Ohmic contact can be formed between magnesium and silicon as published by J. Kanicki in Appl. Phys. Lett. Vol. 53, p 1943 (1988);

FIG. 2A is a cross-sectional view of a thin-film photovoltaic device according to a first embodiment of the present invention;

FIG. 2B is a flowchart showing a method for manufacturing a thin-film photovoltaic device according to a first embodiment of the present invention;

FIG. 3A is a cross-sectional view of a thin-film photovoltaic device according to a second embodiment of the present invention;

FIG. 3B is a flowchart showing a method for manufacturing a thin-film photovoltaic device according to a second embodiment of the present invention;

FIG. 4A is a cross-sectional view of a thin-film photovoltaic device according to a third embodiment of the present invention; and

FIG. 4B is a flowchart showing a method for manufacturing a thin-film photovoltaic device according to a third embodiment of the present invention.

### DETAILED DESCRIPTION OF THE PREFERRED EMBODIMENT

The present invention can be exemplified but not limited by various embodiments as described hereinafter.

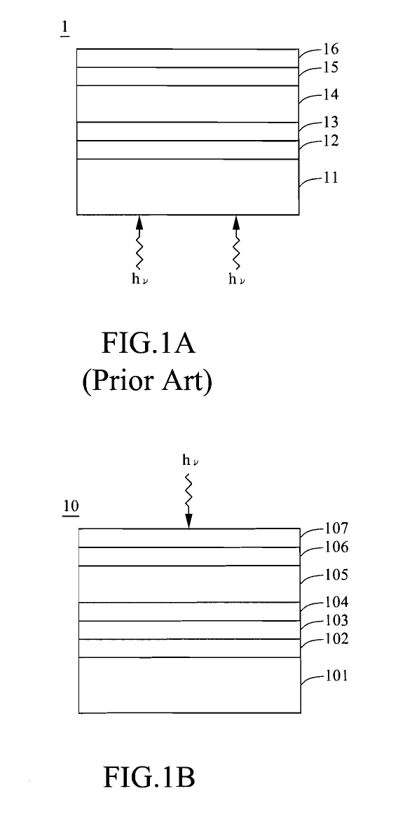

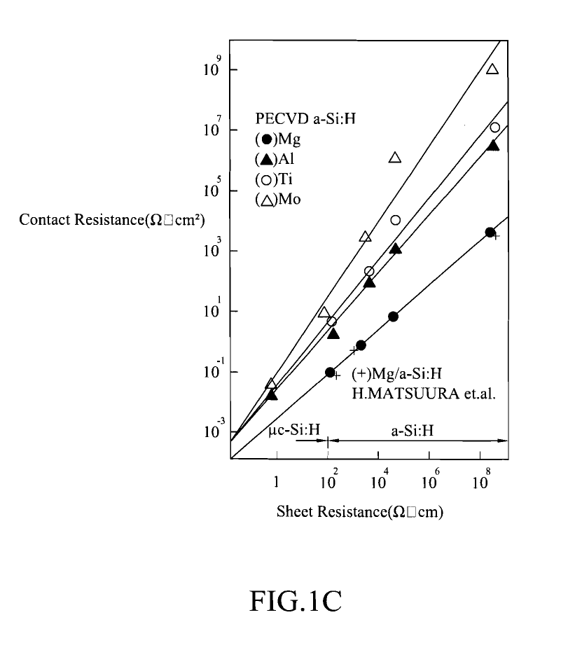

Please refer to FIG. 1, which shows that an excellent Ohmic contact can be formed between magnesium and silicon as published by J. Kanicki in Appl. Phys. Lett. Vol. 53, p 1943 (1988). It is evident that enhanced Ohmic contact can be formed between magnesium and silicon. Accordingly, the present invention provides a thin-film photovoltaic device with enhanced Ohmic contact between the semiconductor layer and the metal electrode layer to improve the opto-electronic performances of the thin-film photovoltaic device.

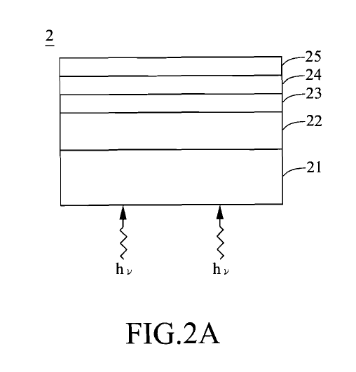

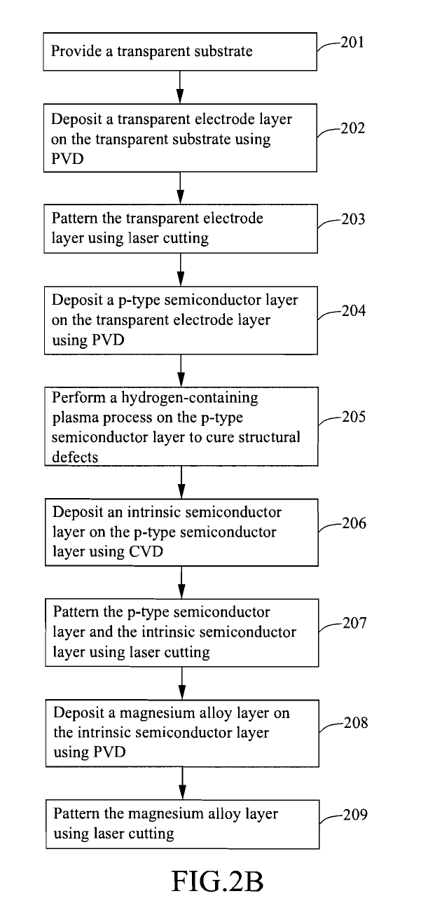

Please refer to FIG. 2A, which is a cross-sectional view of a thin-film photovoltaic device according to a first embodiment of the present invention. In the present embodiment, thin-film photovoltaic device 2 comprises: a transparent substrate 21; a transparent electrode layer 22, formed on the transparent substrate 21; a p-type semiconductor layer 23, formed on the transparent electrode layer 22; an intrinsic semiconductor layer 24, formed on the p-type semiconductor layer 23; and a metal layer 25, formed on the intrinsic semiconductor layer 24.

FIG. 2B is a flowchart showing a method for manufacturing a thin-film photovoltaic device according to a first embodiment of the present invention. The method comprises steps as described herein:

In Step 201, a transparent substrate is provided.

In Step 202, a transparent electrode layer is deposited on the transparent substrate using physical vapor-phase deposition (PVD).

In Step 203, the transparent electrode layer is patterned using laser cutting.

In Step 204, a p-type semiconductor layer is deposited on the transparent electrode layer using physical vapor-phase deposition (PVD).

In Step 205, a hydrogen-containing plasma process is performed on the p-type semiconductor layer to cure structural defects

In Step 206, an intrinsic semiconductor layer is deposited on the p-type semiconductor layer using chemical vapor-phase deposition (CVD).

In Step 207, the p-type semiconductor layer and the intrinsic semiconductor layer are patterned using laser cutting.

In Step 208, a magnesium alloy layer is deposited on the intrinsic semiconductor layer using physical vapor-phase deposition (PVD).

In Step 209, the magnesium alloy layer is patterned using laser cutting.

In the present embodiment, the transparent substrate 21 can be made of glass. The transparent electrode layer 22 may comprise transparent conductive oxide (TCO) such as zinc oxide (ZnO), tin oxide (SnO) or indium tin oxide (ITO).

More particularly, the intrinsic semiconductor layer 24 is a light absorption layer capable of absorbing incoming electro-magnetic radiation within a specific wavelength range to generate electron-hole pairs. The p-type semiconductor layer 23 is a hole-transporting layer capable of transporting holes in the generated electron-hole pairs to the transparent electrode layer 22. In the present embodiment, the p-type semiconductor layer 23 and the intrinsic semiconductor layer 24 are silicon-containing semiconductor layers. In the present embodiment, the metal layer 25 comprises magnesium. Preferably, the metal layer 25 comprises a copper-magnesium alloy. The magnesium particles in the copper-magnesium alloy are out-diffused due to the thermal effect during manufacture to form a metal electrode and thus an excellent Ohmic contact is formed between the metal electrode and the intrinsic silicon semiconductor layer 24 to effectively reduce the resistance at the Schottky contact and improve the performances of the thin-film photovoltaic device 2. In the present invention, the metal layer 25 comprising a copper-magnesium alloy is an electron-transporting layer replacing the conventional n-type semiconductor layer. Meanwhile, the copper-magnesium alloymetal layer 25 is a conductive electrode and capable of transporting electrons in the generated electron-hole pairs.

On the other hand, the p-type silicon semiconductor layer 23 and the metal layer 25 in the present embodiment are deposited by physical sputtering without using gaseous dopants to avoid cross-contamination of gaseous dopants during the formation of the intrinsic semiconductor layer 24 by PECVD in the same chamber so as to prevent the performances of the device from being degraded.

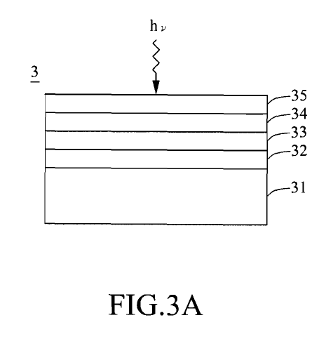

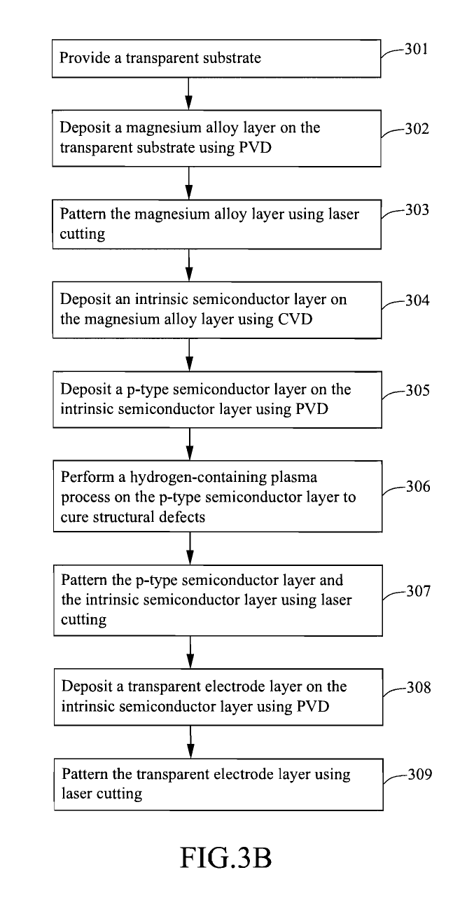

FIG. 3A is a cross-sectional view of a thin-film photovoltaic device according to a second embodiment of the present invention. In the present embodiment, the thin-film photovoltaic device 3 comprises: a transparent substrate 31; a metal layer 32, formed on the transparent substrate 31; an intrinsic semiconductor layer 33, formed on the metal layer 32; a p-type semiconductor layer 34, formed on the intrinsic semiconductor layer 33; and a transparent electrode layer 35, formed on the p-type semiconductor layer 34.

FIG. 3B is a flowchart showing a method for manufacturing a thin-film photovoltaic device according to a second embodiment of the present invention. The method comprises steps as described herein:

In Step 301, a transparent substrate is provided.

In Step 302, a magnesium alloy layer is deposited on the transparent substrate using physical vapor-phase deposition (PVD).

In Step 303, the magnesium alloy layer is patterned using laser cutting.

In Step 304, an intrinsic semiconductor layer is deposited on the magnesium alloy layer using chemical vapor-phase deposition (CVD).

In Step 305, a p-type semiconductor layer is deposited on the intrinsic semiconductor layer using physical vapor-phase deposition (PVD).

In Step 306, a hydrogen-containing plasma process is performed on the p-type semiconductor layer to cure structural defects.

In Step 307, the p-type semiconductor layer and the intrinsic semiconductor layer are patterned using laser cutting.

In Step 308, a transparent electrode layer is deposited on the p-type semiconductor layer using physical vapor-phase deposition (PVD).

In Step 309, the transparent electrode layer is patterned using laser cutting.

In the present embodiment, the transparent substrate 31 can be made of glass. The transparent electrode layer 35 may comprise transparent conductive oxide (TCO) such as zinc oxide (ZnO), tin oxide (SnO) or indium tin oxide (ITO).

More particularly, the intrinsic semiconductor layer 33 is a light absorption layer capable of absorbing incoming electro-magnetic radiation within a specific specific wavelength range to generate electron-hole pairs. The p-type semiconductor layer 34 is a hole-transporting layer capable of transporting holes in the generated electron-hole pairs to the transparent electrode layer 35. In the present embodiment, the p-type semiconductor layer 34 and the intrinsic semiconductor layer 33 are silicon-containing semiconductor layers. In the present embodiment, the metal layer 32 comprises magnesium. Preferably, the metal layer 32 comprises a copper-magnesium alloy. The magnesium particles in the copper-magnesium alloy are out-diffused due to the thermal effect during manufacture to form a metal electrode and thus an excellent Ohmic contact is formed between the metal electrode and the intrinsic silicon semiconductor layer 33 to effectively reduce the resistance at the Schottky contact and improve the performances of the thin-film photovoltaic device 3. In the present invention, the metal layer 32 comprising a copper-magnesium alloy is an electron-transporting layer replacing the conventional n-type semiconductor layer. Meanwhile, the copper-magnesium alloymetal layer 32 is a conductive electrode and capable of transporting electrons in the generated electron-hole pairs.

On the other hand, the p-type silicon semiconductor layer 34 and the metal layer 32 in the present embodiment are deposited by physical sputtering without using gaseous dopants to avoid cross-contamination of gaseous dopants during the formation of the intrinsic semiconductor layer 33 by PECVD in the same chamber so as to prevent the performances of the device from being degraded.

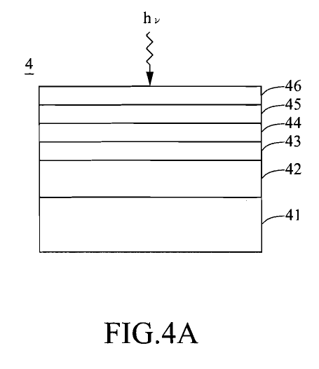

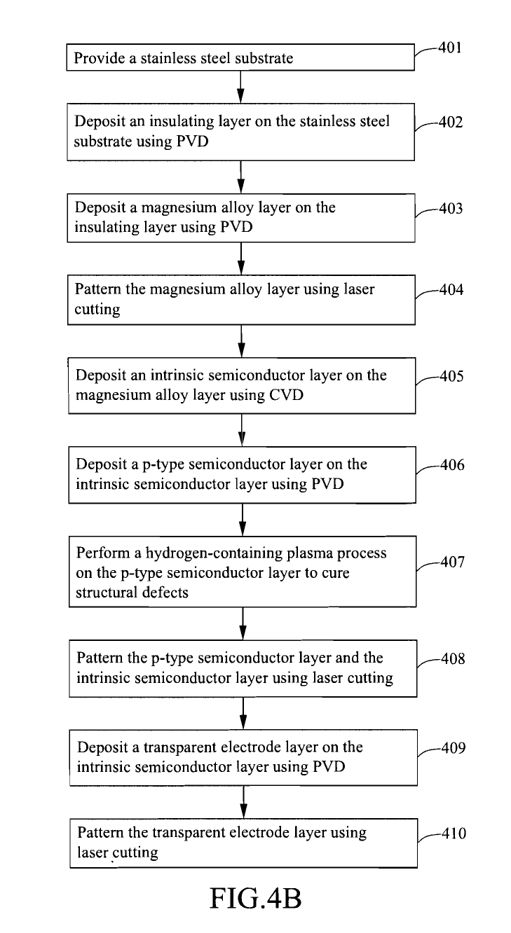

FIG. 4A is a cross-sectional view of a thin-film photovoltaic device according to a third embodiment of the present invention. In the present embodiment, the thin-film photovoltaic device 4 comprises: a stainless steel substrate 41; an insulating layer 42, formed on the stainless steel substrate 41; a metal layer 43, formed on the insulating layer 42; an intrinsic semiconductor layer 44, formed on the metal layer 43; a p-type semiconductor layer 45, formed on the intrinsic semiconductor layer 44; and a transparent electrode layer 46, formed on the p-type semiconductor layer 45.

FIG. 4B is a flowchart showing a method for manufacturing a thin-film photovoltaic device according to a third embodiment of the present invention. The method comprises steps as described herein:

In Step 401, a stainless steel substrate is provided.

In Step 402, an insulating layer is deposited on the stainless steel substrate using physical vapor-phase deposition (PVD).

In Step 403, a magnesium alloy layer is deposited on the insulating layer using physical vapor-phase deposition (PVD).

In Step 404, the magnesium alloy layer is patterned using laser cutting.

In Step 405, an intrinsic semiconductor layer is deposited on the magnesium alloy layer using chemical vapor-phase deposition (CVD).

In Step 406, a p-type semiconductor layer is deposited on the intrinsic semiconductor layer using physical vapor-phase deposition (PVD).

In Step 407, a hydrogen-containing plasma process is performed on the p-type semiconductor layer to cure structural defects.

In Step 408, the p-type semiconductor layer and the intrinsic semiconductor layer are patterned using laser cutting.

In Step 409, a transparent electrode layer is deposited on the p-type semiconductor layer using physical vapor-phase deposition (PVD).

In Step 410, the transparent electrode layer is patterned using laser cutting.

In the present embodiment, the stainless steel substrate 41 can be a flexible substrate. The insulating layer 42 may comprise silicon dioxide (SiO₂) to electrically isolate the stainless steel substrate 41 and the metal layer 43. The transparent electrode layer 46 may comprise transparent conductive oxide (TCO) such as zinc oxide (ZnO), tin oxide (SnO) or indium tin oxide (ITO).

More particularly, the intrinsic semiconductor layer 44 is a light absorption layer capable of absorbing incoming electro-magnetic radiation within a specific wavelength range to generate electron-hole pairs. The p-type semiconductor layer 45 is a hole-transporting layer capable of transporting holes in the generated electron-hole pairs to the transparent electrode layer 46. In the present embodiment, the p-type semiconductor layer 45 and the intrinsic semiconductor layer 44 are silicon-containing semiconductor layers. In the present embodiment, the metal layer 43 comprises magnesium. Preferably, the metal layer 43 comprises a copper-magnesium alloy. The magnesium particles in the copper-magnesium alloy are out-diffused due to the thermal effect during manufacture to form a metal electrode and thus an excellent Ohmic contact is formed between the metal electrode and the intrinsic silicon semiconductor layer 44 to effectively reduce the resistance at the Schottky contact and improve the performances of the thin-film photovoltaic device 4. In the present invention, the metal layer 43 comprising a copper-magnesium alloy is an electron-transporting layer replacing the conventional n-type semiconductor layer. Meanwhile, the copper-magnesium alloymetal layer 43 is a conductive electrode and capable of transporting electrons in the generated electron-hole pairs.

On the other hand, the p-type silicon semiconductor layer 45 and the metal layer 43 in the present embodiment are deposited by physical sputtering without using gaseous dopants to avoid cross-contamination of gaseous dopants during the formation of the intrinsic semiconductor layer 44 by PECVD in the same chamber so as to prevent the performances of the device from being degraded.

Accordingly, the present invention discloses a thin-film photovoltaic device and a method for manufacturing the thin-film photovoltaic device comprising a magnesium alloy layer to enhance the Ohmic contact between the semiconductor layer and the metal electrode layer to improve the opto-electronic performances. Therefore, the present invention is novel, useful, and non-obvious.

Although the present invention has been disclosed and illustrated with reference to particular embodiments, the principles involved are susceptible for use in numerous other embodiments that will be apparent to persons skilled in the art. The present invention is, therefore, to be limited only as indicated by the scope of the appended claims.

What is claimed is:

1. A thin-film photovoltaic device, comprising:
a transparent substrate;
a transparent electrode layer, formed on the transparent substrate;
a p-type semiconductor layer, formed on the transparent electrode layer;
an intrinsic semiconductor layer, formed on the p-type semiconductor layer; and
a metal layer, formed on the intrinsic semiconductor layer.

2. The thin-film photovoltaic device as recited in claim 1, wherein the intrinsic semiconductor layer is a light absorption layer capable of absorbing incoming electro-magnetic radiation within a specific wavelength range to generate electron-hole pairs, the p-type semiconductor layer is a hole-transporting layer capable of transporting holes in the generated electron-hole pairs to the transparent electrode layer, and the metal layer is an electron-transporting layer being a conductive electrode and capable of transporting electrons in the generated electron-hole pairs.

3. The thin-film photovoltaic device as recited in claim 1, wherein the metal layer comprises magnesium.

4. The thin-film photovoltaic device as recited in claim 1, wherein the metal layer comprises a copper-magnesium alloy.

5. The thin-film photovoltaic device as recited in claim 1, wherein the transparent substrate is made of glass.

6. The thin-film photovoltaic device as recited in claim 1, wherein the p-type semiconductor layer and the intrinsic semiconductor layer comprise silicon.

7. A method for manufacturing a thin-film photovoltaic device, comprising steps of:
providing a transparent substrate;
depositing a transparent electrode layer on the transparent substrate using physical vapor-phase deposition (PVD);
patterning the transparent electrode layer using laser cutting;
depositing a p-type semiconductor layer on the transparent electrode layer using physical vapor-phase deposition (PVD);
performing a hydrogen-containing plasma process on the p-type semiconductor layer to cure structural defects;
depositing an intrinsic semiconductor layer on the p-type semiconductor layer using chemical vapor-phase deposition (CVD);
patterning the p-type semiconductor layer and the intrinsic semiconductor layer using laser cutting;
depositing a magnesium alloy layer on the intrinsic semiconductor layer using physical vapor-phase deposition (PVD); and
patterning the magnesium alloy layer using laser cutting.

8. A thin-film photovoltaic device, comprising:
a transparent substrate;
a metal layer, formed on the transparent substrate;
an intrinsic semiconductor layer, formed on the metal layer;
a p-type semiconductor layer, formed on the intrinsic semiconductor layer; and
a transparent electrode layer, formed on the p-type semiconductor layer.

9. The thin-film photovoltaic device as recited in claim 8, wherein the intrinsic semiconductor layer is a light absorption layer capable of absorbing incoming electro-magnetic radiation within a specific wavelength range to generate electron-hole pairs, the p-type semiconductor layer is a hole-transporting layer capable of transporting holes in the generated electron-hole pairs to the transparent electrode layer, and the metal layer is an electron-transporting layer being a conductive electrode and capable of transporting electrons in the generated electron-hole pairs.

10. The thin-film photovoltaic device as recited in claim 8, wherein the metal layer comprises magnesium.

11. The thin-film photovoltaic device as recited in claim 8, wherein the metal layer comprises a copper-magnesium alloy.

12. The thin-film photovoltaic device as recited in claim 8, wherein the transparent substrate is made of glass.

13. The thin-film photovoltaic device as recited in claim 8, wherein the p-type semiconductor layer and the intrinsic semiconductor layer comprise silicon.

14. A method for manufacturing a thin-film photovoltaic device, comprising steps of:
providing a transparent substrate;
depositing a magnesium alloy layer on the transparent substrate using physical vapor-phase deposition (PVD);
patterning the magnesium alloy layer using laser cutting;
depositing an intrinsic semiconductor layer on the magnesium alloy layer using chemical vapor-phase deposition (CVD);
depositing a p-type semiconductor layer on the intrinsic semiconductor layer using physical vapor-phase deposition (PVD);
performing a hydrogen-containing plasma process on the p-type semiconductor layer to cure structural defects;
patterning the p-type semiconductor layer and the intrinsic semiconductor layer using laser cutting;
depositing a transparent electrode layer on the intrinsic semiconductor layer using physical vapor-phase deposition (PVD); and
patterning the transparent electrode layer using laser cutting.

15. A thin-film photovoltaic device, comprising:
a stainless steel substrate;
an insulating layer, formed on the stainless steel substrate;
a metal layer, formed on the insulating layer;
an intrinsic semiconductor layer, formed on the metal layer;
a p-type semiconductor layer, formed on the intrinsic semiconductor layer; and
a transparent electrode layer, formed on the p-type semiconductor layer.

16. The thin-film photovoltaic device as recited in claim 15, wherein the intrinsic semiconductor layer is a light absorption layer capable of absorbing incoming electro-magnetic radiation within a specific wavelength range to generate electron-hole pairs, the p-type semiconductor layer is a hole-transporting layer capable of transporting holes in the generated electron-hole pairs to the transparent electrode layer, and the metal layer is an electron-transporting layer being a conductive electrode and capable of transporting electrons in the generated electron-hole pairs.

17. The thin-film photovoltaic device as recited in claim 15, wherein the metal layer comprises magnesium.

18. The thin-film photovoltaic device as recited in claim 15, wherein the metal layer comprises a copper-magnesium alloy.

19. The thin-film photovoltaic device as recited in claim 15, wherein the insulating layer comprises silicon dioxide.

20. The thin-film photovoltaic device as recited in claim 15, wherein the p-type semiconductor layer and the intrinsic semiconductor layer comprise silicon.

21. A method for manufacturing a thin-film photovoltaic device, comprising steps of:
providing a stainless steel substrate;
depositing an insulating layer on the stainless steel substrate using physical vapor-phase deposition (PVD);
depositing a magnesium alloy layer on the insulating layer using physical vapor-phase deposition (PVD);
patterning the magnesium alloy layer using laser cutting;
depositing an intrinsic semiconductor layer on the magnesium alloy layer using chemical vapor-phase deposition (CVD);
depositing a p-type semiconductor layer on the intrinsic semiconductor layer using physical vapor-phase deposition (PVD);
performing a hydrogen-containing plasma process on the p-type semiconductor layer to cure structural defects;
patterning the p-type semiconductor layer and the intrinsic semiconductor layer using laser cutting;
depositing a transparent electrode layer on the intrinsic semiconductor layer using physical vapor-phase deposition (PVD); and
patterning the transparent electrode layer using laser cutting.
